(19) United States
(12) Patent Application Publication
(10) Pub. No.: US 2008/0165286 A1
(43) Pub. Date: Jul. 10, 2008

(54) Controller and User Interface for Dialogue Enhancement Techniques

(75) Inventors: Hyen-O Oh, Goyang-si (KR); Yang-Won Jung, Seoul (KR)

Correspondence Address: FISH & RICHARDSON P.C., PO BOX 1022, MINNEAPOLIS, MN, 55440-1022, US

(73) Assignee: LG ELECTRONICS INC., Seoul (KR)

(21) Appl. No.: 11/855,570

(22) Filed: Sep. 14, 2007

Related U.S. Application Data
(60) Provisional application No. 60/844,806, filed on Sep. 14, 2006.
(60) Provisional application No. 60/943,268, filed on Jun. 11, 2007.
(60) Provisional application No. 60/884,594, filed on Jan. 11, 2007.

(51) Int. Cl. H04N 5/445; H04N 5/60; H03G 3/02; H04R 5/00; H04R 29/00

(52) U.S. Cl. 348/569; 381/109; 381/27; 348/738; 381/58; 348/E05.099

(57) ABSTRACT

A plural-channel audio signal (e.g., a stereo audio) is processed to modify a gain (e.g., a volume level or loudness) of an estimated dialogue signal (e.g., dialogue spoken by actors in a movie) relative to other signals (e.g., reflected or reverberated sound). In some aspects, a controller is used to control master volume and dialogue volume. In some aspects, one or more graphical objects and/or user interface elements are used to indicate volume levels and other information.

### SUMMARY AND DETAILED DESCRIPTION OF INVENTION

### SUMMARY

The present invention relates to a method of adjusting a volume of an aural signal contained in audio/video signal only. And, the present invention enables a volume of an aural signal to be effectively adjusted according to a request made by a user in such various devices for playing back audio signals as TV, DMB player, PMP and the like.

### DETAILED DESCRIPTION OF INVENTION

In case of delivering an aural signal only in an environment without background noise/transmission noise, a listener barely has difficulty in recognizing transmitted voice. If a volume of the transmitted voice is low, it is able to overcome the low volume by raising a playback volume.

Yet, in a general environment, where voice contained movie, drama, sports or the like is played back in theatre, TV or the like, for transmitting the voice together with music, various sound effects and the like, a listener may have difficulty in recognizing voice due to music, various sound effects or background/transmission noise. In this case, a playback volume is raised to enhance recognition of the voice. If so, such background sound transmitted together with the voice as music, sound effect and the like is increased as well. Hence, the listener feels uncomfortable due to the excessively raised volume.

To overcome such a problem, a method of giving a gain to a specific frequency band of an input signal or attenuating an input signal or a method of reducing a dynamic range corresponding to a signal level is available.

A method for overcoming the above problem according to the present invention is based on giving a gain to a signal located in a specific space in a manner of dividing a signal spatially.

For instance, in case that a transmitted signal is stereo, it is able to use a method comprising the steps of generating a center channel virtually, giving a gain to the center channel, and adding the center channel to L/R channel. In this case, it is a normal way that the virtually generated center channel is obtained from simply adding L and R channels together. This is represented as follows.

Cᵥᵢᵣₜᵤₐₗ=Lᵢₙ+Rᵢₙ

Cₒᵤₜ=F_{center}(G_{center}×Cᵥᵢᵣₜᵤₐₗ)

Lₒᵤₜ=G_{L}×Lᵢₙ+Cₒᵤₜ

Rₒᵤₜ=G_{R}×Rᵢₙ+Cₒᵤₜ

In this case, L_in and R_in mean inputs of L and R channels, respectively. L_out and R_out mean outputs of L and R channels, respectively. C_virtual and C_out are values used in an intermediate process and mean a virtual center channel and a processed virtual center output, respectively. G_center is a gain for determining a size of a virtual center channel. And, G_L and G_R mean gains applied to L and R channel input values, respectively. For clarity and convenience, it is in general that G_L or G_R is set to 1.

In addition to the above-described method, it is able to use a method of applying a band-pass filter for emphasizing or suppressing a specific frequency as well as applying a gain to a virtual center channel. In this case, it is able to apply a band-pass filter using f_center.

In case of utilizing this method, if a volume of a virtual center channel is raised using G_center, there may exist a limitation that other signal components of music, sound effect and the like contained in conventional L and R channels are amplified as well as an aural signal.

Moreover, in case of adopting band-pass filtering by utilizing f_center, it may be able to obtain an effect that enhancing voice articulation. Yet, signals of voice, music, background sound and the like are distorted, whereby a listener may experience unpleasantness.

### DETAILED DESCRIPTION OF INVENTION

As methods for solving the above-mentioned problem according to the present invention, the following two methods are further available. Firstly, a method of adjusting a volume of an aural signal from a transmitted audio signal effectively is proposed. Subsequently, an apparatus and method for adjusting a volume of an aural signal more effectively is then proposed.

### 1. Method of Adjusting Volume of Aural Signal

In general, an aural signal is concentrated on a center channel in a multi-channel signal environment. In case of 5.1, 6.1 or 7.1 channel for movie or the like, words or dialogue is normally allocated to a center channel. If an introduced audio signal is such a multi-channel signal, it is able to obtain a sufficient effect by adjusting a gain of the center channel only.

Yet, if an audio signal fails to include a center channel (e.g., stereo), a method of applying a gain amounting to a specific size to a center area (hereinafter named an aural space area) on which it is estimated that voice may be concentrated from an existing channel is necessary.

### 1-a) Case of Multi-Channel Input Signal Including Center Channel

In case of currently and widely used 5.1, 6.1 and 7.1 channels, center channels are included. As mentioned in the foregoing description, it is able to obtain specific effect sufficiently by adjusting a gain of center only. In this case, the center channel is a channel containing dialogue therein in general and is symbolically represented. And, the present invention is not limited to the center channel only.

1-a-1) Case that Output Channel Includes Center Channel

In this case, assuming that output center channel and input center channel are represented as C_out and C_in, respectively, they can be configured as the following formula.

C_out=f_center(G_center*C_in)

In this case, G_center and f_center are a specific gain and a filter (function) applied to a center channel and can be configured according to usages, respectively. In some cases, f_center is firstly applied and G_center is then applied.

C_out=G_center*f_center(C_in)

1-a-2) Case that Output Channel Does not Include Center Channel

If an output channel does not include a center channel, C_out having its gain adjusted in the above manner is introduced into L and R channels. This can be configured by the conventional method using the following formulas.

Lₒᵤₜ=G_{L}×Lᵢₙ+Cₒᵤₜ

Rₒᵤₜ=G_{R}×Rᵢₙ+Cₒᵤₜ

In this case, it is able to add C_out operated by 1/sqrt(2) to maintain signal power.

### 1-b) Case of Multi-Channel Input Signal not Including Center Channel

If a center channel is not included, it is able to solve the problem by finding an aural space area estimated that voice is concentrated thereon from a given input signal and applying a specific gain.

The conventional method is based on ‘prologic’ and the like and has considerable disadvantages in estimating an aural space area.

The present invention solves this problem by analyzing an input signal spatially.

According to Sine Law, when a sound source (i.e., virtual source in the drawing) is located at a specific position, this is represented using two speakers in a manner of adjusting a gain of each of the channels by the following formulas.

$${x}_{i} ( k ) = {g}_{i} x ( k )$$

$$\frac{sin ϕ}{sin {ϕ}_{0}} = \frac{{g}_{1} - {g}_{2}}{{g}_{1} + {g}_{2}}$$

In this case, sine is replaceable by tangent.

On the contrary, assume that sizes of signals entering two speakers, i.e., g1 and g2 are known, it is able to know a position of a sound source represented by a currently entering signal.

In case that a center speaker does not exist, left and right front speakers located in front virtually play a role as a center speaker by playing back sound to be contained in a center speaker.

In this case, gains similar to each other for sound in a center area, i.e., g1 and g2 are given for the two speakers, thereby obtaining an effect that a virtual source is located at a center position in the drawing.

Considering Sine Law formula, if g1 and g2 have values similar to each other, an element on a right side has a value close to 0. This means that sine φ has a value close to 0, i.e., φ has a value close to 0. This results in letting apposition of a virtual source lie at a center.

Using such a phenomenon inversely, the present invention estimates an aural space area.

If a virtual source lies at a center, two channels L and R constructing a virtual center have gains similar to each other. And, it is then able to adjust a gain of an aural space area by adjusting a gain value for a signal estimated as a virtual center.

Inter-channel correlation is used to be utilized for aural space area estimation as well as level information o each channel. For instance, in case that inter-channel correlation is low, an input signal is regarded as spreading wide rather than located at a specific position in a space. Hence, it is highly probable that it is not an aural signal. On the other hand, in case of high correlation, since an input signal occupies a prescribed position in a space, it is highly probable that an input signal is a voice or sound effect (e.g., sound of closing a door) occupying a position rather than background noise.

Hence, it is able to estimate an aural space area more effectively using level information of each channel and correlation together.

Moreover, since bands of aural signal on a frequency gather within 100 Hz˜8 kHz, various signals such as voice, music, sound effect and the like are contained in an audio signal in general. So, it is able to raise aural space area estimating performance by configuring a classifier for deciding whether a transmitted signal is voice, music or the like prior to estimating such an aural space area. Besides, the classifier is applicable after an aural space area has been estimated.

Details of the present invention are explained in the following description.

1-b-1) Control on Time Domain

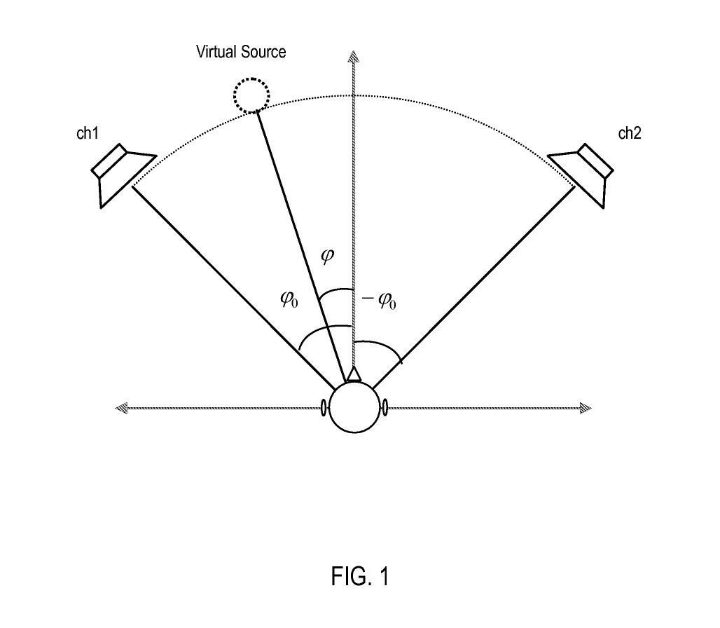

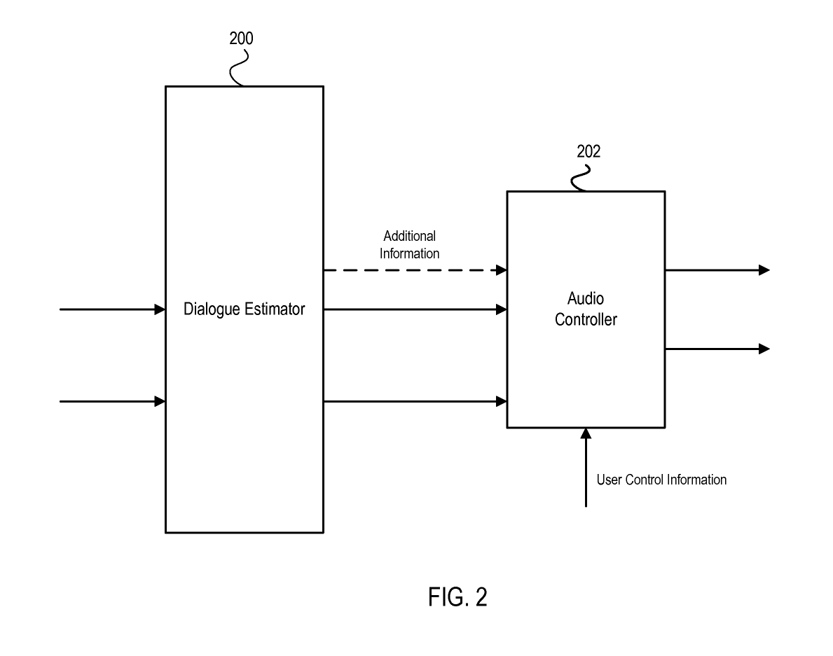

Referring to FIG. 2, an aural space area is estimated using an input signal. An output is then obtained by applying a user-specific gain to the estimated aural space area. By estimating the aural space area, it is able to generate additional information necessary for gain adjustment.

User control information may contain voice level adjustment and the like.

Since it is able to analyze an audio signal into music, voice, reverberation, background noise or the like, sizes and properties of the respective elements are adjustable in audio control.

1-b-2) Processing Per Subband

Estimating each aural space area per band after dividing a signal into a plurality of subbands is more effective than estimating to control an aural space area for whole bands of an input signal. For instance, voice in a transmitted audio signal is not contained on a specific frequency region but may be contained on another specific frequency region. In this case, it is able to use a region, in which it is estimated that voice is contained, for aural space area estimation.

Methods for obtaining a subband signal may include various methods such as polyphase filterbank, QMF, hybrid filterbank, DFT, MDCT and the like. And, every method is applicable.

1-b-3) Utilization of Classifier

Methods for enabling a classifier to be installed in various ways are explained in the following description.

In this case, a classifier performs a function of classifying a signal into one of determined classes by a method of analyzing statistical or perceptional characteristics of signal. For instance, a classifier discriminates whether an input signal corresponds to voice, music, sound effect, mute section or the like and then outputs the discriminated value. And, an output of the classifier may correspond to a soft decision output such as probability or specific gravity of voice existence and the like instead of a hard decision output such as voice, music and the like.

Positions of the classifier, as shown in the above drawings, can be decided in various ways.

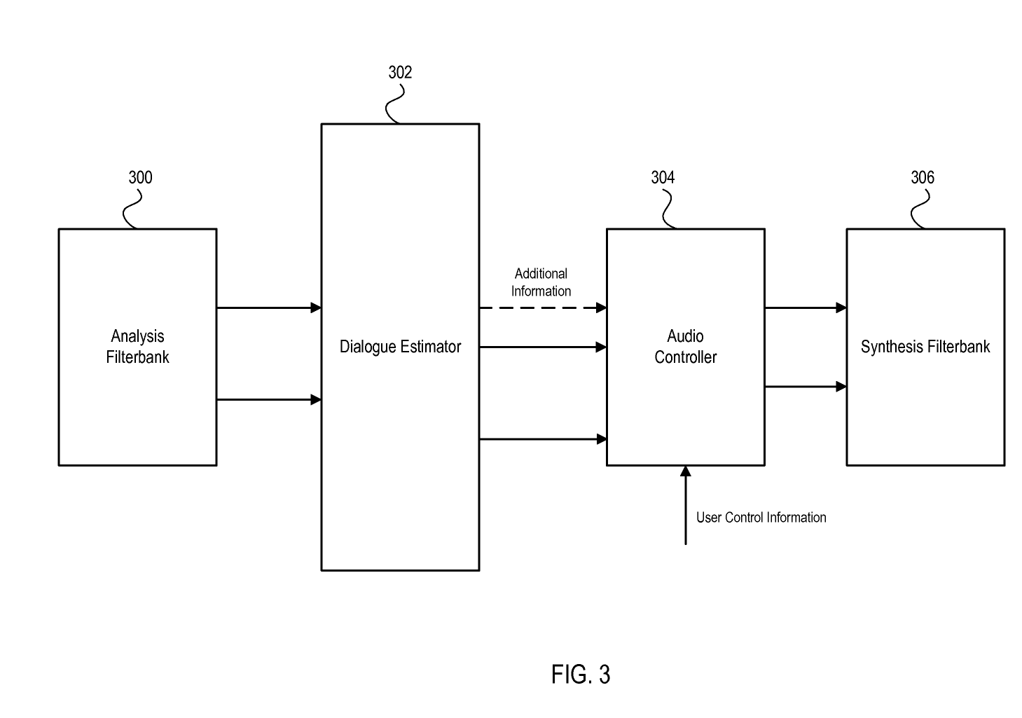

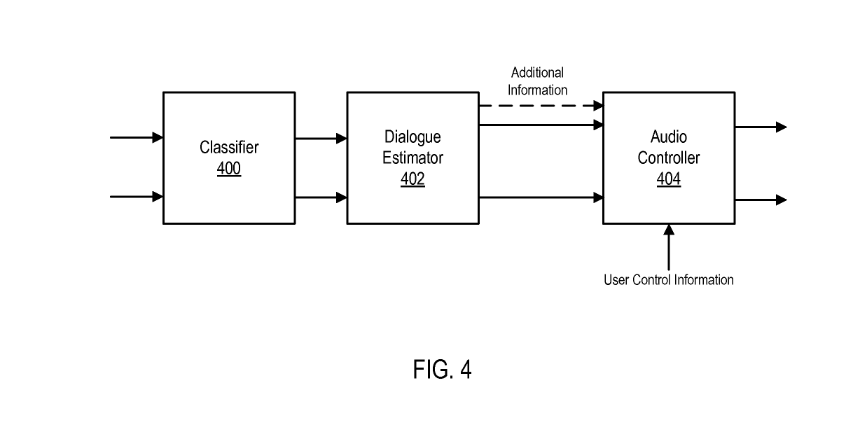

Referring to FIG. 4, after a signal has passed through the classifier, if it is decided that voice exists within the corresponding signal, subsequent steps are carried out. If it is decided that voice does not exist, it is able to let a received signal pass intact.

If user control information relates not to a volume of voice but to another audio signal (e.g., volume of music is raised higher as volume of voice is left intact), after the classifier has decided that it is a music signal, it is able to adjust the volume of the music only in a subsequent process.

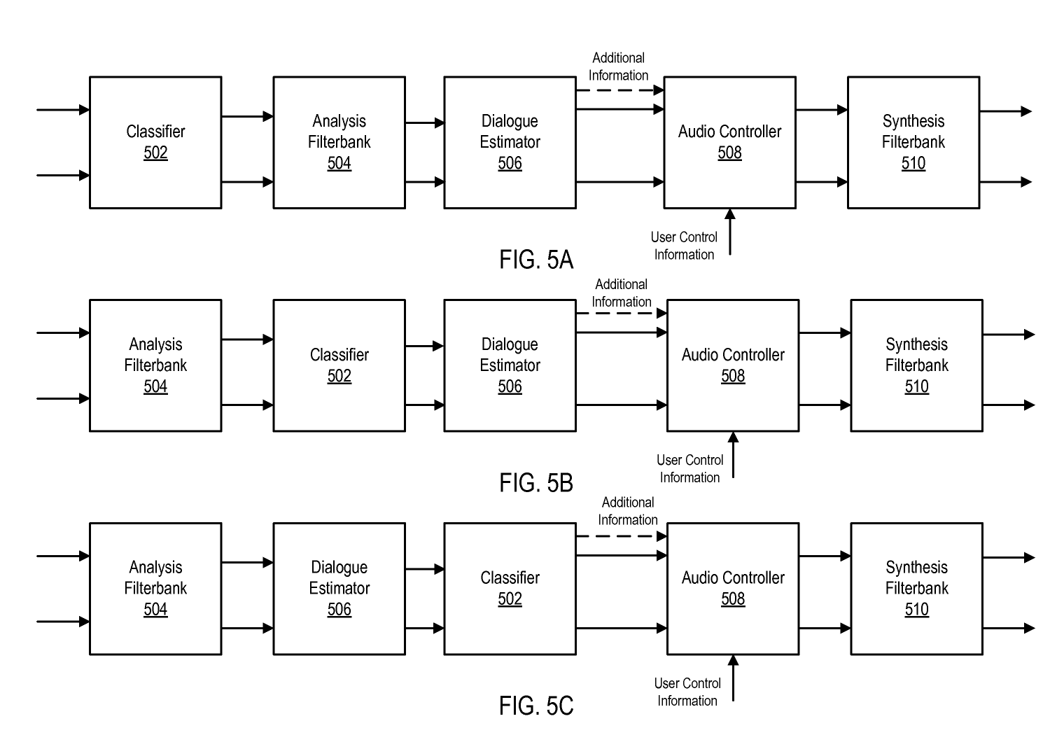

Referring to FIG. 5, the classifier is applied behind the filterbank. It is able to obtain an output differently classified per a band according to a frequency (subband) at a specific timing point. And, it is able to adjust characteristics of audio (e.g., voice volume increment, reverberation effect decrement, etc.) played back according to each case and user control information.

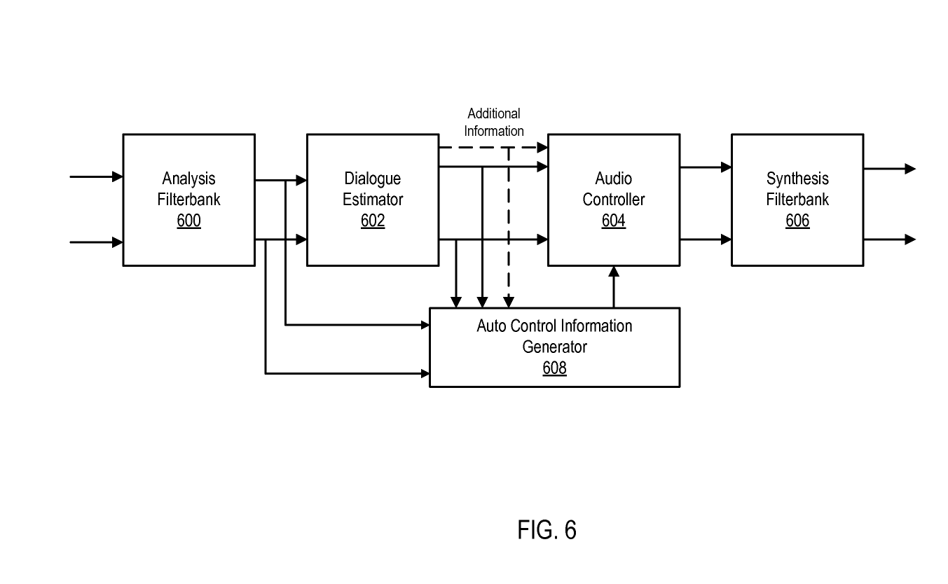

Referring to FIG. 6, the classifier is applied behind aural space area estimation. For instance, the classifier can be effectively applied to a case that music signal is concentrated on a center to be misconceived as an aural space.

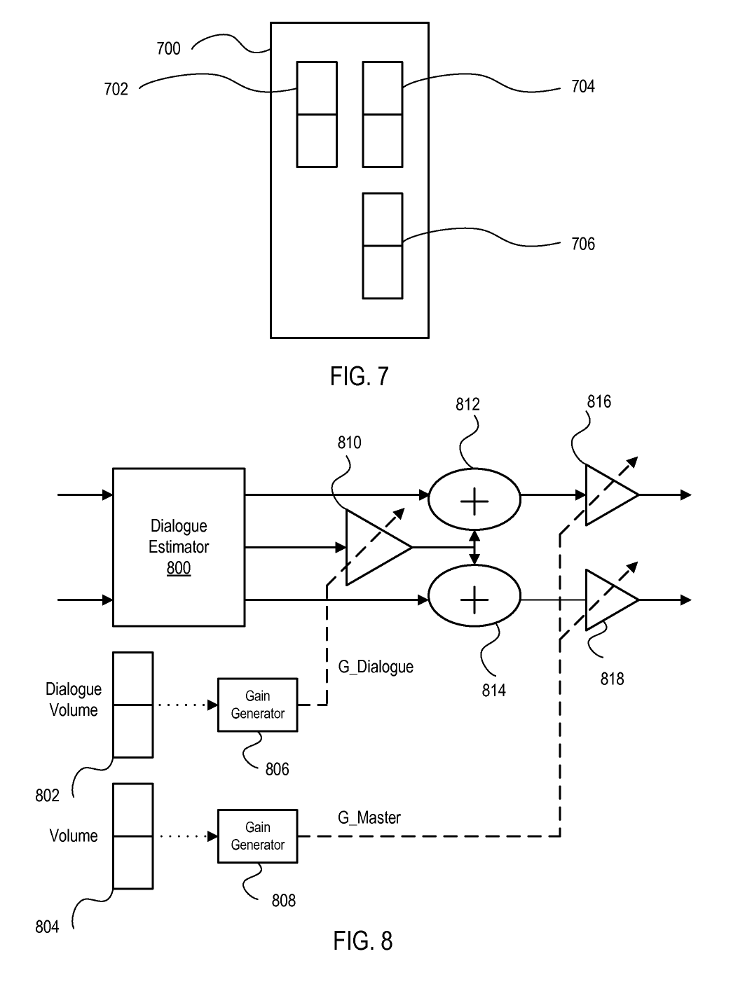

FIG. 7 shows an example that the classifier is applied on a time axis.

Thus, various examples for applying the classifier have been described. And, it is understood that the present invention is applicable to more examples.

1-b-4) Automatic Voice Volume Adjusting Function

In the precedent example, in case that a user fails to perceive an aural signal well, the user adjusts a voice volume and the like by himself. Further, the present invention proposes a system equipped with an automatic voice volume adjusting function.

(In FIG. 8, for clarity and convenience of description, a classifier block is not shown. And, it is apparent that a classifier can be included in FIG. 8 as the same configuration shown in FIG. 4-7. Moreover, filterbank/synthesis filterbank may not be included).

For instance, if the object of audio control lies in maintaining a ratio over a prescribed value by comparing a volume of an aural signal to that of whole audio signal or other audio signal (background music, noise, sound effect, etc.) except the aural signal, an auto control information generator compares a size of an aural space area signal to a size of an input signal or a size of other audio signal. If it is lower than a specific level, it is able to adjust the size of the aural space area signal into a prescribed level higher than the specific level.

For instance, assuming that P_dialogue is a size of an aural space area signal, P_input is a size of an input signal, and P_other_audio is a size of other audio signal, it is able to automatically correct a gain by the following formulas.

if P_ratio=P_dialogue/P_input<P_threshold,

G_dialogue=function(P_threshold/P_ratio)

[In this case, P_ratio is defined as P_dialogue/P_input, P_threshold is a preset value, and G_dialogue is a gain value that will be applied to an aural space area (the same concept of the formerly explained G_center).]

And, a user is able to set P_threshold to be suitable to user's taste.

On the contrary, it is able to maintain a relative size smaller than a predetermined value by the following formulas.

if P_ratio=P_dialogue/P_input<P_threshold2,

G_dialogue=function(P_threshold2/P_ratio)

The above-explained auto control information generation enables a size of background music, reverberation and space sense to be maintained as a user-specific predetermined relative value according to a playback audio signal as well as a voice volume.

Through this, a listener is able to listen to an aural signal on a high volume in a noisy background environment for example or listen to a signal on an originally transmitted level or lower in a quiet environment.

### 2. Method of Adjusting Aural Signal Size Effectively

The present invention proposes a method and apparatus for adjusting a volume of an aural signal from a transmitted audio signal more effectively based on the former invention described in the section 1.

The present invention mainly includes a controller and a method of feeding back information currently controlled by a user to the user.

### 2-a) Controller

For convenience and clarity of explanation, a remote controller of TV is explained for example. And, it is understood that the present invention is applicable to a remote controller of an audio system or the like as well as that of the TV. Moreover, it is also understood that the present invention is identically applicable to a method of adjusting a DMB player, a PMP player, a car audio system, a TV or an audio main body.

2-a-1) Configuration #1 of Independent Controller

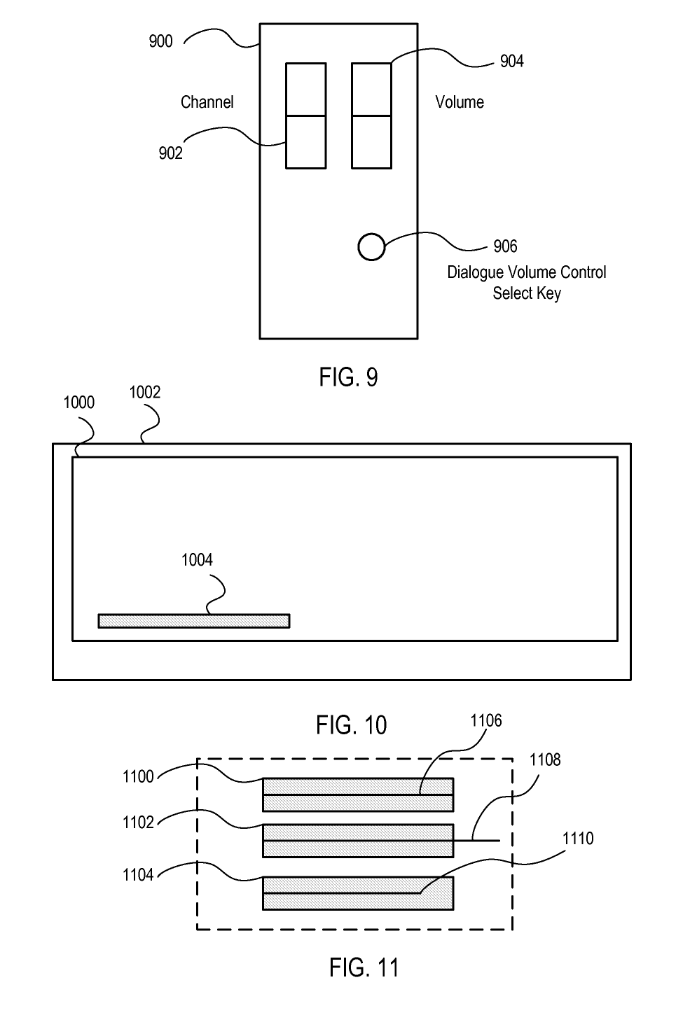

Referring to FIG. 9, a remote controller of a general TV is provided with a channel/volume up/down controller. Separately, the present invention provides a method of using an additional up/down controller for adjusting a volume of a specific audio signal. According to the present invention, the specific audio signal may include a signal of an aural space area. By utilizing such a separate controller, it is able to adjust a volume of an aural signal more conveniently and efficiently.

FIG. E1 shows a process for actually applying conventional volume control and conventional dialog volume control to a signal. For clarity of explanation, the formerly-described detailed function blocks are omitted but necessary parts are shown in the drawing.

2-a-2) Configuration #1 of Independent Controller

FIG. 10 shows not an up/down-enabling controller but a controller enabling on/off only. So, this controller enables the following control executions.

a) Aural space area signal volume adjustment on/off

b) Phased increment of aural space area signal

In case of a), if a volume adjustment is turned on, a signal of an aural space area is increased by a preset gain value (e.g., 6 dB). If the controller is pushed again, a gain value can be switched to 0.

And, if the volume adjustment is turned on, the aforesaid automatic voice volume adjusting function can be enabled.

In case of b), as a button is repeatedly pushed (e.g., 0→3 dB→6 dB→12 dB→0), a volume gain is sequentially incremented to circulate.

This adjustment facilitates a user to intuitively use the function proposed by the present invention.

Matching between input keys and real operative circuit can be induced from FIG. E1.

2-a-3) Utilization of Conventional Controller

FIG. 11 seems similar to FIG. 10 but shows a control selector instead of a controller. Adjustment is enabled by the following method.

If ‘dialogue control select’ is selected, ‘volume’ is used in adjusting a volume of an aural space area signal instead of performing a conventional volume function. It is able to release ‘dialogue control select’ by re-pressing a corresponding button. Alternatively, the selected ‘dialogue control select’ can be automatically released after elapse of specific time.

Once the ‘dialogue control select’ is selected, in order to inform a user that a function of a volume key is changed, it is able to devise various methods for indicating the corresponding information on a remote controller. For instance, the corresponding information is displayed on a screen, a color or symbol of a ‘dialogue control select’ key is changed, a color or symbol of a volume key is changed, or a key height is varied if the ‘dialogue control select’ key is selected.

The above adjusting method provides the following advantages. First of all, a user is facilitated to operate a volume adjustment in aspect of intuitive concept. Secondly, the audio control enables various audios (e.g., voice, background music, reverberation, etc.) to be controlled without increasing the number of buttons.

In performing various audio controls, a user is able to select attribute of audio to control using ‘dialogue control select’ button. For instance, whole→voice→music→sound effect→whole→ . . . .

### 2-b) Delivering Control Information to User

2-b-1) Method #1 of Utilizing OSD

For clarity and convenience of explanation, OSD (on screen display) of TV is taken as an example. And, it is understood that the present invention is applicable to other kinds of such a medium capable of indicating states of a device as an amplifier OSD, a PMP OSD, an LCD window of amplifier/PMP and the like.

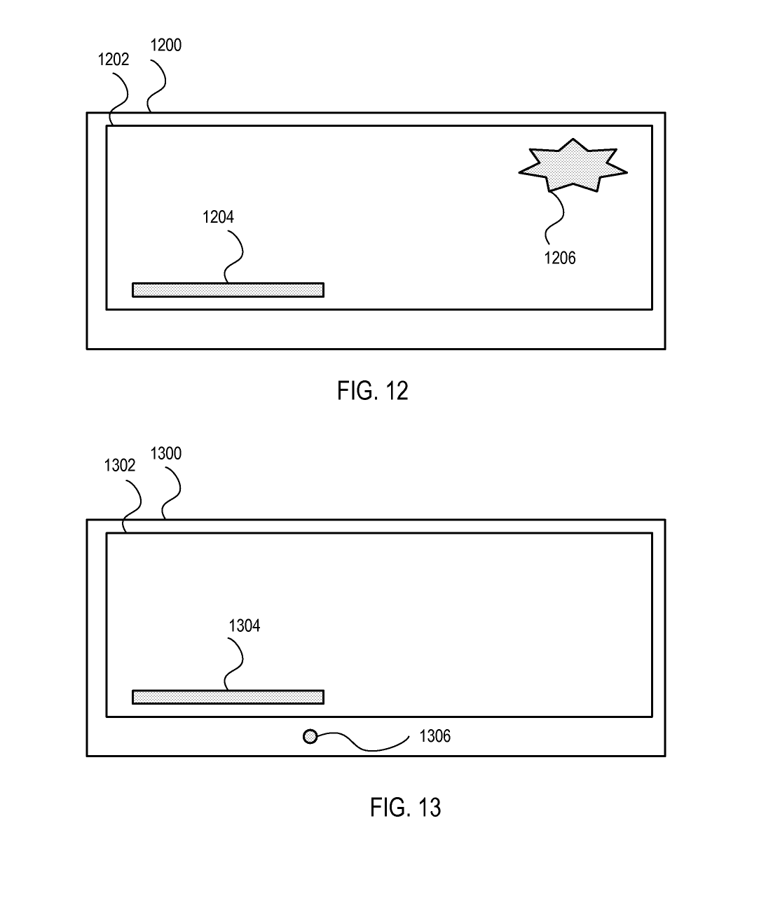

FIG. 12 exemplarily shows OSD of a general TV.

Variation of volume can be represented as digits or a bar shown in the drawing.

FIG. 13 shows a method of displaying a voice volume together in case that a bar type volume is displayed. In the drawing, a length of a straight line in the middle of a bar indicates a size of a voice volume. In (a) of FIG. 13, shown is a case that a voice volume is not separately adjusted. If the volume is not adjusted separately, the voice volume can be represented as having the same value of a total volume. In (b) of FIG. 13, shown is a case that a voice volume is increased. In (c) of FIG. 13, shown is a case that a voice volume is decreased.

The above displaying method is advantageous in that a user always knows a relative value to a voice volume size to enable an efficient adjustment. Moreover, since a voice volume size is displayed together with a conventional volume bar, OSD can be configured efficiently and consistently.

The present invention is not limited to a bar type display. Instead, the present invention is intended to include: a) Method of displaying both a total volume and a volume to be controlled (e.g., voice volume in the present example) together; and b) Method of providing a volume to be controlled (e.g., voice volume in the present example) in a manner of comparing the volume to a total volume.

Namely, for example, the volumes are represented as two bars. Alternatively, bars differing from each other in color and width are represented for the volumes as overlapped with each other.

In case that there are at least two kinds of volumes to be controlled, the above method is applicable thereto.

In case that there are at least kinds of volumes to be displayed by independent controls, a method of displaying information about a control only is additionally available to prevent user's confusion.

(For instance, assuming that reverberation and voice volume are adjustable, if the reverberation is adjusted only while the voice volume is maintained intact, a total volume and a reverberation volume are displayable in the above manner. In this case, it is preferable that they differ from each other in color or shape to enable intuitive discrimination.

2-b-2) Method #2 of Utilizing OSD

The 2-b-2) relates to a method of displaying a volume.

In the following description, a method of displaying information on a currently adjusted control entity is explained.

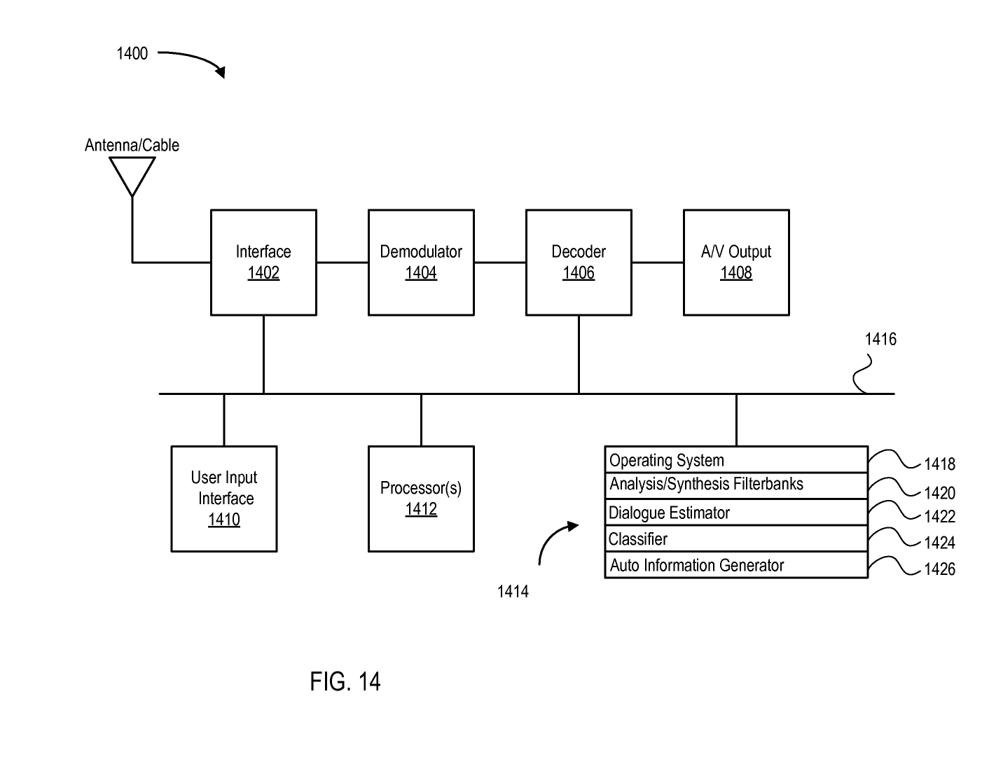

FIG. 14 shows an example for a method of displaying that a volume currently adjusted by a user is a voice volume. As mentioned in the foregoing description of the present invention, the method of adjusting the voice volume by displaying the volume bar together with a basic volume is effective. Yet, the present invention enables information on a currently adjusted volume to be given to a user.

Moreover, the present invention proposes a method of indicating a size of voice by differentiating color, brightness or size of the information indicating the voice instead of indicating a size of voice volume by providing a separate volume bar. This displaying method, as described in 2-a-2), is more effectively usable in case of adjusting a size with the phased circulation.

2-b-3) Utilization of Separate Indicator

In order to indicate a type of a currently adjusted volume, it can be displayed on OSD. Alternatively, a separate indicator, as shown in FIG. 15, is utilized to indicate the type. In this case, it is advantageous in that a TV screen is not affected by the indication.

2-b-4) Display on Control Equipment

As mentioned in the foregoing description of 2-a-3), if the ‘dialogue control select’ is selected, a user needs to be informed that a function of a volume key has been changed. This can be carried out by varying a color of the ‘dialogue control select’ key. Alternatively, it is able to devise other methods for enabling a user to recognize the change on a remote controller. For this, various a color of a volume key is changed. If the ‘dialogue control select’ key is selected, a height of the corresponding key is varied.

What is claimed is:

1. An apparatus comprising:
a dialogue volume control;
a master volume control; and
a circuit operatively coupled to the dialogue volume control and the master volume control and configurable for generating a dialogue volume control signal and a master volume control signal for use in separately adjusting the dialogue volume and the master volume of an audio signal, respectively.

2. The apparatus of claim 1, wherein the dialogue volume control signal is used for adjusting dialogue volume level of an audio signal relative to the master volume level or the volume level of one or more other audio signals.

3. The apparatus of claim 1, wherein the dialogue volume control signal is used for boosting or attenuating dialogue volume.

4. The apparatus of claim 1, where the dialogue volume of the audio signal increases or decreases incrementally by a predetermined amount in response to user interaction with the dialogue volume control.

5. The apparatus of claim 1, where the visual appearance of the dialogue volume control or the master volume control is modified to indicate its function or activation.

6. The apparatus of claim 1, where the dialogue volume control signal is used to generate one or more graphical objects on a display device for providing visual feedback indicating dialogue volume level.

7. The apparatus of claim 6, where a first graphical object indicates master volume level and a second graphical object indicates dialogue volume level relative to master volume level or relative to a volume level of another audio signal.

8. The apparatus of claim 1, where the dialogue volume control signal is used to generate an indicator that dialogue volume control is active.

9. An apparatus comprising:
a volume control;
a dialogue volume control select; and
a circuit operatively coupled to the volume control and configurable for generating a dialogue volume control signal if the dialogue volume control select is activated, and for generating a master volume control signal to the device if the dialogue volume control select is not activated.

10. The apparatus of claim 9, where the dialogue volume of an audio signal increases or decreases incrementally by a predetermined amount in response to user interaction with the dialogue volume control.

11. The apparatus of claim 9, where the visual appearance of the volume control or the dialogue volume control select is modified to indicate its function.

12. The apparatus of claim 9, where the dialogue volume control signal is used to generate an indicator that dialogue volume control is active for display by the apparatus or another device.

13. A method comprising:
receiving a first volume control signal;
receiving a second volume control signal;
responsive to the first volume control signal, displaying a first graphical object for indicating a first volume level; and
responsive to the second volume control signal, displaying a second graphical object within or proximate to the first graphical object for indicating a second volume level relative to the first volume level.

14. The method of claim 13, where the first graphical object is a bar and the second graphical object is a line extending within the bar to visually indicate the second volume level relative to the first volume.

15. The method of claim 13, where the first volume level is a master volume level of a plural-channel audio signal and the second volume level is a dialogue volume level relative to the master volume level.

16. A method comprising:
obtaining a plural-channel audio signal;
estimating a center channel signal and at least left and right channel signals using the audio signal;
modifying a first gain of the center channel signal using a gain factor generated by a dialogue volume control;
generating a combined channel signal including the left and right channel signals and the modified center channel signal; and
modifying a second gain of the combined channel signal using a master volume control.

17. A system comprising:
a controller configurable for generating a dialogue volume control signal; and
a receiver configurable for receiving the dialogue volume control signal, and for using the dialogue volume control signal to modify a dialogue volume level of a plural-channel audio signal being processed by the television receiver without modifying the volume level of at least a portion of the plural-channel audio signal.

18. The system of claim 17, further comprising:
a display operatively coupled to the receiver and configurable for displaying one of more graphical objects indicating a first volume level and a second volume level relative to the first volume level.

19. The system of claim 18, where a first graphical object is a bar for indicating the first volume level and a second graphical object is a line extending within the bar to visually indicate the second volume level relative to the first volume level.

20. The system of claim 18, where the first volume level is a master volume level of the plural-channel audio signal and the second volume level is a dialogue volume level relative to the master volume level.

21. The system of claim 17, where the controller further comprises:
a dialogue volume control; and
a circuit operatively coupled to the volume control and configurable for generating the dialogue volume control signal in response to user interaction with the dialogue volume control.
